(19) United States
(12) Patent Application Publication
(10) Pub. No.: US 2026/0118422 A1
(43) Pub. Date: Apr. 30, 2026

(54) PROGRAMMABLE LOGIC BUILT-IN SELF-TEST (LBIST) MULTIPLE INPUT SIGNATURE REGISTER (MISR) FOR HARDWARE ENABLED BIST STORED IN SEPARATE MEMORY

(71) Applicant: QUALCOMM Incorporated, San Diego, CA (US)

(72) Inventor: Rajesh Kumar TIWARI, Bangalore (IN)

(21) Appl. No.: 18/929,343

(22) Filed: Oct. 28, 2024

(51) Int. Cl. G01R 31/317; G01R 31/3181; G01R 31/3185

(52) U.S. Cl. CPC G01R 31/31724; G01R 31/31813; G01R 31/318555

(57) ABSTRACT

An on-chip logic built-in self-test (LBIST) apparatus has a first autonomous in-system test (AIT) read only memory (ROM) storing a built-in self-test (BIST) pattern and a first set of jump instructions for reading a multiple input signature register (MISR) signature from a second AIT memory. The second AIT memory stores the MISR signature and a second set of jump instructions. The second set of jump instructions returns program execution to the first AIT ROM.

### FIELD OF THE DISCLOSURE

Aspects of the present disclosure generally relate to computing devices, and more particularly to a programmable logic built-in self-test (LBIST) multiple input signature register (MISR) for hardware enabled BIST that is stored in random access memory (RAM) or field programmable read-only memory (PROM).

### BACKGROUND

Functional safety is an aspect of computer systems design, particularly in automotive, aerospace, industrial automation, and medical device contexts. Functional safety includes implementing mechanisms to increase the likelihood that a system behaves predictably and safely in the presence of faults. Functional safety standards provide frameworks for the development, validation, and verification of safety systems. These standards include rigorous risk assessment, hazard analysis, and the use of redundant and diverse design techniques to mitigate potential hazards. Strategies for implementing functional safety involve built-in self-tests (BISTs), safety integrity levels (SILs), fail-safe and fail-operational modes, and comprehensive safety case documentation to demonstrate that safety specifications are satisfied throughout the product lifecycle.

In the automotive industry, vehicles are rated via an Automotive Safety Integrity Level (ASIL) rating system. ASIL ratings, ranging from ASIL-A to ASIL-D, categorize the severity of potential hazards and the rigor specified to mitigate the hazards. ASIL-A represents the lowest safety integrity level and is awarded to systems implementing fewer safety measures, while ASIL-D signifies the highest safety integrity level and is awarded to systems implementing more stringent safety protocols. These ratings guide automotive development, validation, and verification processes to increase the likelihood that automotive systems can operate safely, even in the presence of faults. The ASIL framework encompasses risk assessment, hazard analysis, and the implementation of redundant and diverse safety mechanisms to prevent or mitigate failures. Hardware enabled BIST is one technique for ensuring safety specifications are satisfied.

### SUMMARY

Aspects of the present disclosure are directed to an on-chip logic built-in self-test (LBIST) apparatus. The apparatus has a first autonomous in-system test (AIT) read only memory (ROM) storing a built-in self-test (BIST) pattern and a first set of jump instructions for reading a multiple input signature register (MISR) signature from a second AIT memory. The second AIT memory stores the MISR signature and a second set of jump instructions. The second set of jump instructions returns program execution to the first AIT ROM.

In aspects of the present disclosure, a method for performing a logic built-in self-test (LBIST) includes reading a built-in self-test (BIST) pattern from a first autonomous in-system test (AIT) read only memory (ROM). The method also includes applying the BIST pattern to a circuit under test to obtain an output signature. The method further includes jumping execution to a second AIT memory. The method still further includes reading a multiple input signature register (MISR) signature from the second AIT memory and jumping execution to the first AIT ROM. The method also includes comparing the output signature to the MISR signature.

Other aspects of the present disclosure are directed to an apparatus. The apparatus has one or more memories and one or more processors coupled to the memory. The processor(s) is configured to read a built-in self-test (BIST) pattern from a first autonomous in-system test (AIT) read only memory (ROM). The processor(s) is also configured to apply the BIST pattern to a circuit under test to obtain an output signature. The processor(s) is further configured to jump execution to a second AIT memory. The processor(s) is still further configured to read a multiple input signature register (MISR) signature from the second AIT memory and jump execution to the first AIT ROM. The processor(s) is also configured to compare the output signature to the MISR signature.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of a system-on-a-chip (SOC), in accordance with various aspects of the present disclosure.

FIG. 2 illustrates an example of an automobile including systems that may be adapted, configured, or operated, in accordance with various aspects of the present disclosure.

FIG. 3 is a block diagram illustrating an Automotive Safety Integrity Level (ASIL) data path.

FIG. 4 is a block diagram illustrating a system for executing hardware enabled logic built-in self-test (LBIST) processes.

FIG. 5 is a block diagram illustrating a system with programmable read only memory (ROM) for storing logic built-in self-test (LBIST) multiple input signature register (MISR) patterns, in accordance with various aspects of the present disclosure.

FIG. 6 is a block diagram illustrating a system with random access memory (RAM) for storing logic built-in self-test (LBIST) multiple input signature register (MISR) patterns, in accordance with various aspects of the present disclosure.

FIG. 7 is a flow chart illustrating an example process performed, for example, by a built-in self-test (BIST) device, in accordance with various aspects of the present disclosure.

FIG. 8 is a block diagram illustrating a design workstation used for circuit, layout, and logic design of BIST components, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method practiced using other structure, functionality, or structure and functionality in addition to or other than the various aspects of the disclosure set forth. It should be understood that any aspect of the disclosure disclosed may be embodied by one or more elements of a claim.

The word “exemplary” is used to mean “serving as an example, instance, or illustration.” Any aspect described as “exemplary” is not necessarily to be construed as preferred or advantageous over other aspects.

Although particular aspects are described, many variations and permutations of these aspects fall within the scope of the disclosure. Although some benefits and advantages of the preferred aspects are mentioned, the scope of the disclosure is not intended to be limited to particular benefits, uses or objectives. Rather, aspects of the disclosure are intended to be broadly applicable to different technologies, system configurations, networks, and protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

Several aspects of functional safety management will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

As described, automotive systems executing safety critical applications or functions are rated via an Automotive Safety Integrity Level (ASIL) rating system. The ASILs may be defined in a specific safety standard, such as international organization for standardization (ISO) 26262. For example, the ASILs may provide a risk classification scheme for certain electrical and electronic systems of road vehicles. ISO 26262 provides four ASILs including ASIL-A, ASIL-B, ASIL-C, and ASIL-D. ASIL-D is the highest classification and corresponds to the highest level of safety measures for avoiding an unreasonable residual risk, and ASIL-A is the lowest classification and corresponds to the lowest level of safety measures. ASIL ratings, ranging from ASIL-A (lowest) to ASIL-D (highest), categorize the severity of potential hazards and the rigor specified to mitigate the hazards.

Development of advanced driver assistance systems (ADASs) and automated driving systems (ADSs), as well as associated safety and mission critical applications in the automotive industry, have caused many safety critical applications to specify ASIL-D safety ratings. As a result, vehicle and chip manufacturers have developed conventional approaches to develop and manufacture ASIL-D hardware. In one approach, a system-on-a-chip (SOC) and memory elements include several components along an inline data path. The components are each individually designed and manufactured to satisfy ASIL specifications (e.g., ASIL-D or ASIL-C specifications), enabling the entire data path to reach ASIL-D or ASIL-C status. Hardware enabled built-in self-test (BIST) is one technique for ensuring safety specifications are satisfied.

Critical safety systems, the central processing unit (CPU) cluster, and other critical systems may be tested upon boot up to ensure compliance with the safety specifications. Each of these components may be subject to hardware enabled BIST when powering on and powering off the vehicle before operating the vehicle in the field.

BIST is a technique to test functionality of integrated circuits (ICs) by embedding test circuitry within an IC to allow the IC to periodically test its own operation. Logic BIST (LBIST) uses a pseudo-random pattern generator to generate test patterns that are applied to internal scan chains of the circuit under test. The response to the test patterns input to the circuit under test are compressed into a signature. Comparisons to a multiple input signature register (MISR) pattern determine whether the signature is correct, indicating the circuit under test is properly functioning.

The MISR patterns are stored on-chip in read only memory (ROM). The ROM images, however, are frozen during chip design (e.g., metal tape out (MTO)), and thus, changes to the patterns after chip design are cost prohibitive, preventing updates to the ROM image on silicon. It would be desirable to be able to update the MISR patterns after tape out, without impacting boot up performance (e.g., speed).

Aspects of the present disclosure segregate the MISR signature from rest of the vector memory by adding a small amount (e.g., 1-2 KB) of programable ROM or random access memory (RAM), instead of traditional ROM. The LBIST MISR signature may be stored in a dedicated field programmable ROM or RAM, instead of the regular ROM in a same address space. Jump instructions to switch from the traditional ROM to programmable ROM or RAM for MISR reads and vice versa are included as part of the test pattern. For the RAM implementation, existing system programmable ROM (PROM) stores the MISR signature in dedicated spaces and rows. The hardware BIST control unit (HBCU) copies data from the existing PROM to the RAM. As a result of segregating the MISR signature from the rest of the test pattern, any late timing exceptions (due to post silicon findings or fixes) leading to BIST MISR updates can be incorporated without redesigning the chip or increasing boot time.

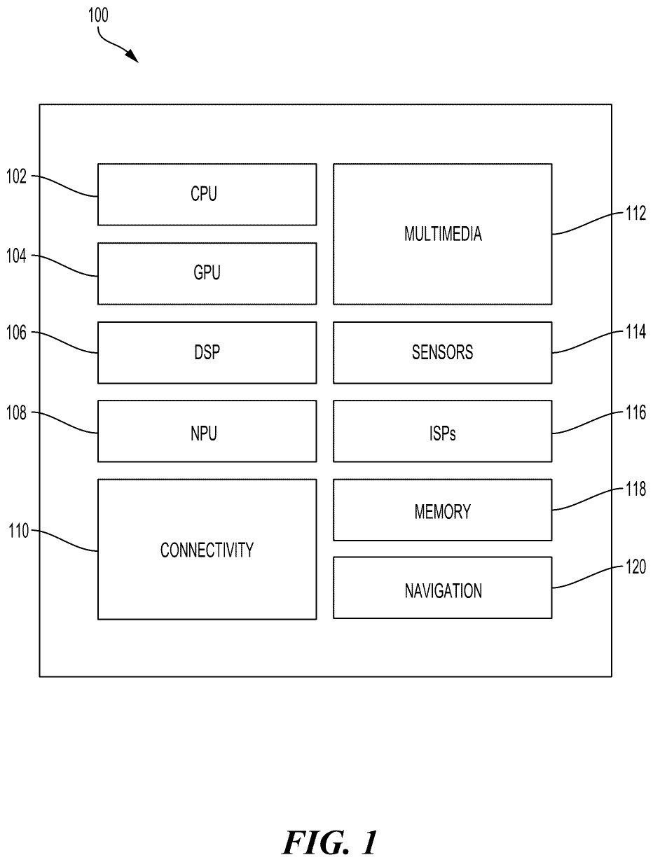

FIG. 1 illustrates an example implementation of a system-on-a-chip (SOC) 100, which may include a central processing unit (CPU) 102 or a multi-core CPU configured for logic built-in self-test (LBIST) operations. Variables (e.g., neural signals and synaptic weights), system parameters associated with a computational device (e.g., neural network with weights), delays, frequency bin information, and task information may be stored in a memory block associated with a neural processing unit (NPU) 108, in a memory block associated with a CPU 102, in a memory block associated with a graphics processing unit (GPU) 104, in a memory block associated with a digital signal processor (DSP) 106, in a memory block 118, or may be distributed across multiple blocks. Instructions executed at the CPU 102 may be loaded from a program memory associated with the CPU 102 or may be loaded from a memory block 118.

The SOC 100 may also include additional processing blocks tailored to specific functions, such as a GPU 104, a DSP 106, a connectivity block 110, which may include fifth generation (5G) connectivity, fourth generation long term evolution (4G LTE) connectivity, Wi-Fi connectivity, USB connectivity, Bluetooth connectivity, and the like, and a multimedia processor 112 that may, for example, detect and recognize gestures. In one implementation, the NPU 108 is implemented in the CPU 102, DSP 106, and/or GPU 104. The SOC 100 may also include a sensor processor 114, image signal processors (ISPs) 116, and/or navigation module 120, which may include a global positioning system.

The SOC 100 may be based on any architecture, such as a complex instruction set (CISC) architecture, an ARM, RISC-V (RISC-five), or any reduced instruction set computing (RISC) architecture. In aspects of the present disclosure, the instructions loaded into the CPU 102 may include code to read a built-in self-test (BIST) pattern from a first autonomous in-system test (AIT) read only memory (ROM). In aspects of the present disclosure, the instructions loaded into the CPU 102 may also include code to apply the BIST pattern to a circuit under test to obtain an output signature. In aspects of the present disclosure, the instructions loaded into the CPU 102 may further include code to jump execution to a second AIT memory. In aspects of the present disclosure, the instructions loaded into the CPU 102 may still further include code to read a multiple input signature register (MISR) signature from the second AIT memory. In aspects of the present disclosure, the instructions loaded into the CPU 102 may also include code to jump execution to the first AIT ROM and compare the output signature to the MISR signature.

According to aspects of the present disclosure, an apparatus includes a LBIST mechanism. The apparatus may include means for reading, means for applying, means for jumping, means for comparing, means for copying, means for updating, and means for triggering.

For example, the means for reading, means for applying, means for jumping, means for comparing, means for copying, means for updating, and means for triggering may be any of the CPU 102, GPU 104, DSP 106, NPU 108, memory 118, central controller 220, CPU cluster 302, computation engines 308, memory controller 310, DRAM 312, system 500, an autonomous in-system test (AIT) controller 404, an application processor subsystem sub server (APSS) 408, an AIT ROM 506, and/or an AIT programmable read only memory 530.

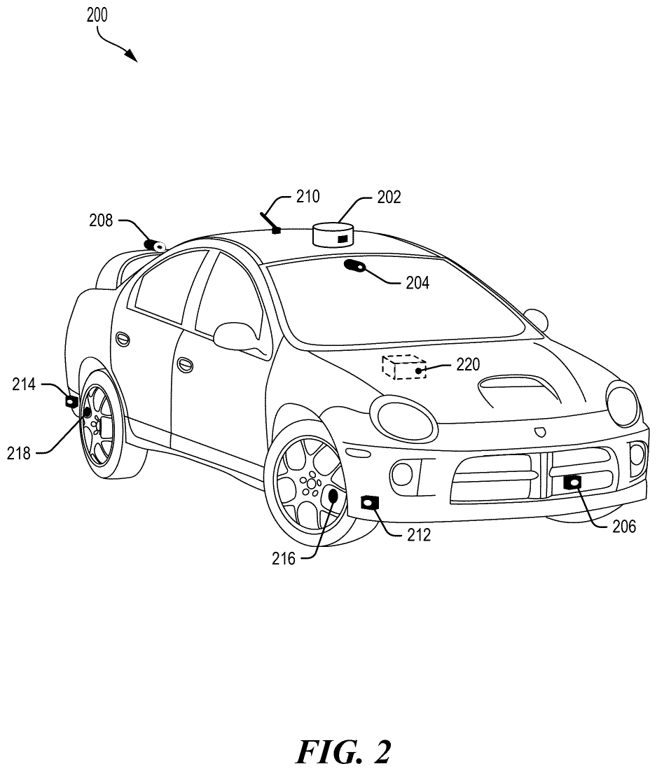

FIG. 2 illustrates an example of an automobile including systems that may be adapted, configured, or operated in accordance with various aspects of this disclosure. The automobile 200 may be equipped with multiple imaging or sensing devices including, for example, cameras 202, 204, 206, 208, 212, 214, and sensors 216, 218. The automobile 200 may include sensors such as tire pressure or braking sensors as the sensors 216, 218. The automobile 200 may also include one or more antennas 210 for radio frequency reception, wireless communication and/or radio navigation using a position location system, such as a global positioning system (GPS). A central controller 220 may be coupled to each of the cameras 202, 204, 206, 208, 212, 214, sensors 216, 218 and antennas 210. The central controller 220 may configure and manage automated systems and/or driver assistance systems. In some implementations, the central controller 220 may be configured to operate as an engine control unit that manages the operation and performance of the engine, motor, motors, or other power systems in the automobile 200. In some instances, the central controller 220 may include an SOC, such as the SOC 100.

Robust data communication links are specified to support the large number of cameras deployed within the automobile 200. In some examples, 20-30 cameras may be deployed to support automation and driver assistance systems. Each camera may be capable of generating data at a rate of between 1-10 gigabits per second (GBps) resulting in aggregate data rates of up to 300 GBps.

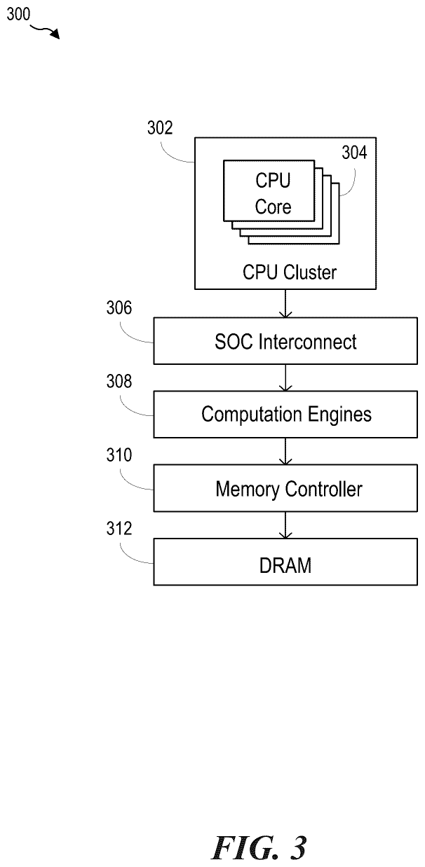

FIG. 3 is a block diagram illustrating an automotive data path 300. As shown, the data path 300 includes a CPU cluster 302. Although a single CPU cluster 302 is depicted for ease of explanation, the present disclosure is not so limited. The CPU cluster 302 includes a set of CPU cores 304 that work concurrently or in parallel to perform computational tasks via workloads distributed across the set of CPU cores 304. The set of CPU cores 304 are respectively interconnected such that each core may perform a portion of a task. Portions of a task may be assigned to each core of the CPU cores 304 by a scheduler (not illustrated) hosted by the CPU cluster 302. The CPU cluster 302 is coupled to an SOC interconnect 306.

The SOC interconnect 306 links various upstream components, such as the CPU cluster 302 and cache (not illustrated) to various downstream components. Additionally, the SOC interconnect 306 facilitates on-chip communications and transaction handling between the upstream components and downstream components on the data path 300. The SOC interconnect 306 is coupled to computation engines 308. The computation engines 308 represent one or more logic structures on the data path 300 that are downstream from the SOC interconnect 306.

The computation engines 308 may include functionally complex, area intensive logic structures on the path to dynamic random access memory (DRAM) in an SOC. For example, the computation engines 308 may include compression engines, encryption engines, a last-level cache, and other computational or memory structures. Compression engines apply compression techniques to reduce the data footprint of data packets transmitted on the data path 300, thus reducing bandwidth specified to transmit the data packets. Encryption engines implement cryptographic techniques to encrypt data packets. A last-level cache serves as high-capacity, low-latency memory storage for upstream components such as the CPU cluster 302. The computation engines 308 are coupled to a memory controller 310.

The memory controller 310 manages data flow between DRAM 312 and upstream components on the data path 300, such as the CPU cluster 302. The memory controller 310 coordinates memory access requests from the upstream components to reduce memory bandwidth and latency. The DRAM 312, coupled to the memory controller 310, serves as the primary volatile storage for the data path 300, providing memory space for stored information. While smaller data packets and data packets specifying low access latency may be stored in a cache within the data path 300, larger data packets and data packets specifying higher access latency may instead by stored in the DRAM 312 by the memory controller 310.

In FIG. 3, each of the components in the data path 300 may be rated as conforming to the highest safety integrity level, e.g., ASIL-D. For instance, ASIL-D may specify strict path protection across complex structures, such as the computation engines 308, memory controller 310, and DRAM 312. Similarly, other safety levels, such as ASIL-C, may also be associated with components in the data path 300. Safety systems, the CPU cluster 302, and other critical systems may be tested upon boot up to ensure compliance with the safety specifications. Each of these components in the data path 300 may be subject to hardware enabled built-in self-test (BIST) when powering on and powering off the vehicle before operating the vehicle in the field.

BIST is a technique to test functionality of ICs by embedding test circuitry within an IC to allow the IC to periodically test its own operation. Logic BIST (LBIST) uses a pseudo-random pattern generator to generate test patterns that are applied to internal scan chains of the circuit under test. The response to the test patterns input to the circuit under test is compressed into a signature. Comparisons to a multiple input signature register (MISR) pattern determine whether the signature is correct, indicating the circuit under test is properly functioning.

The MISR patterns are stored on-chip in read only memory (ROM). The ROM images, however, are frozen during chip design (e.g., metal tape out (MTO)), and thus, changes in the patterns after chip design are cost prohibitive, preventing updates to the ROM image on silicon. It would be desirable to be able to update the MISR patterns after tape out, without impacting boot up performance (e.g., speed).

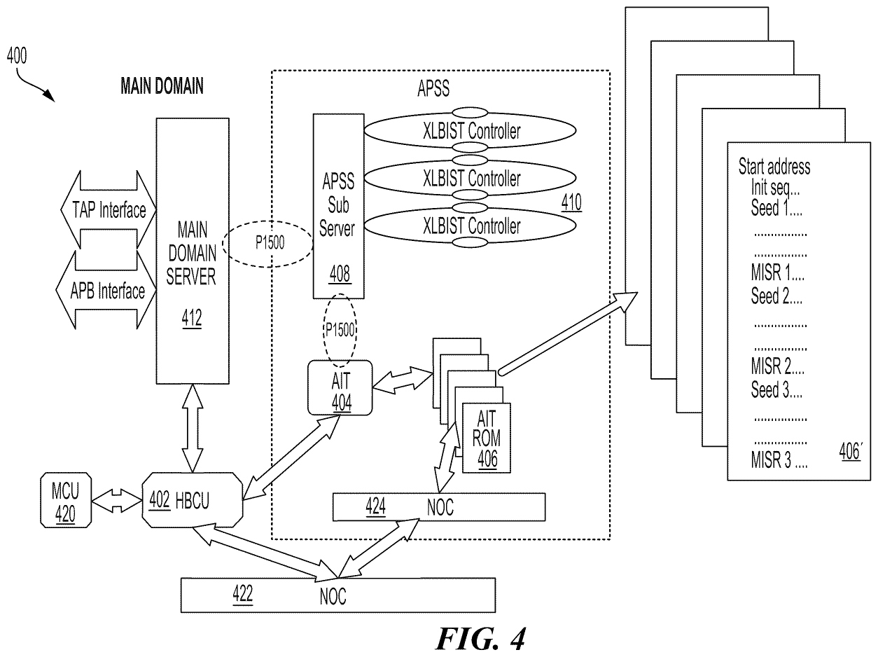

FIG. 4 is a block diagram illustrating a system 400 for executing hardware enabled logic built-in self-test (LBIST) processes. In the example of FIG. 4, a hardware BIST control unit (HBCU) 402 triggers an autonomous in-system test (AIT) controller 404 to start hardware enabled BIST processing. The triggering occurs from a primary boot loader (not shown) when the hardware is booting up. The AIT controller 404 starts the BIST by reading patterns stored in on-chip AIT ROM 406. The AIT controller 404 applies the test patterns through an application processor subsystem sub server (APSS) 408 to x-tolerant logic built-in self-test (XLBIST) controllers 410 using a P1500 interface, for example. The XLBIST controllers 410 test the logic based on the patterns read from the AIT ROM 406. Sample ROM image content 406′ is shown in FIG. 4 and includes seeds that initialize the test design, as well as multiple input signature register (MISR) patterns. The AIT controller 404 determines pass/fail status based on the MISR patterns stored in the AIT ROM 406 and the information received from the APSS sub server 408 and reports the pass/fail status to the HBCU 402, which forwards the information to a main control unit (MCU) 420. If the BIST passes, the MCU 420 allows the boot operation to continue. If the BIST fails, the MCU 420 takes appropriate action.

A main domain server 412 receives input, such as, for example, joint test action group (JTAG) data, via a test access port (TAP) interface and also receives BIST data via a functional interface (e.g., an advanced peripheral bus (APB) interface) for debugging purposes. The main domain server 412 also communicates with the APSS sub server 408, for example, via a P1500 interface. The HBCU 402 communicates with a system network-on-chip (NOC) 422 and an on-chip NOC 424 to provide patches to the AIT ROM 406.

Silicon failures may specify a ROM image change. For example, a mismatch may be seen between a simulation model and actual behavior in the manufactured chip (e.g., in silicon). That is, a hardware enabled BIST may fail due to a difference in an expected response versus an actual response. The system 400 shown in FIG. 4, unfortunately, cannot update or modify patterns containing LBIST MISR data after metal tape out of the chip (e.g., final design stage of the chip process). That is, the ROM image is frozen at tape out. As a result, any MISR signature change necessitated by post silicon LBIST issues will increase the time for chip delivery, thereby increasing chip manufacturing costs.

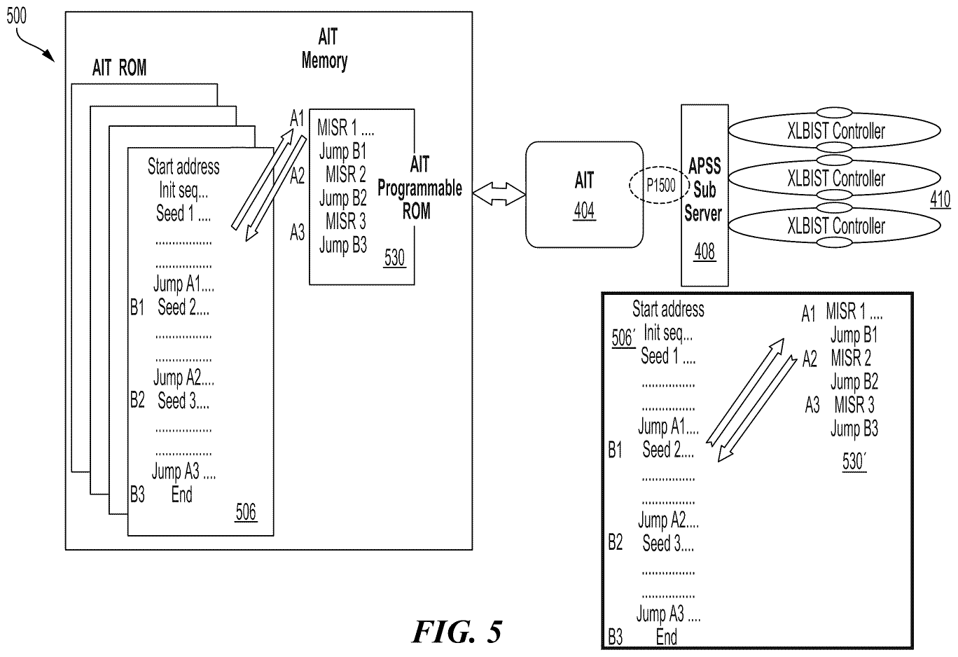

FIG. 5 is a block diagram illustrating a system 500 with a programmable read only memory (ROM) for storing logic built-in self-test (LBIST) multiple input signature register (MISR) patterns, in accordance with various aspects of the present disclosure. In the example of FIG. 5, the AIT ROM 406 of FIG. 4 is split into two separate memory spaces, including an AIT ROM 506 and an AIT programmable ROM (PROM) 530. The BIST MISR signature is separated from the BIST seeds and stored in the programmable ROM 530. As a result, the MISR signature can be programmed after post silicon validation.

The programmable ROM 530 shares an address space with the AIT ROM 506. More specifically, as seen in the enlarged view of the AIT ROM 506′ and the enlarged view of the programmable ROM 530′, AIT JUMP instructions are inserted in the test pattern stored in the AIT ROM 506 to read MISR values from the programmable ROM 530. Jump instructions are also included in the programmable ROM 530 to jump back to the regular ROM addresses for further execution. As a result, the split memory is transparent to the AIT controller 404. The AIT controller 404 does not see the actual memory physical implementation (e.g., AIT ROM 506+programmable ROM 530). The AIT controller 404 sees the AIT ROM 506 and PROM 530 as a single address space.

Importantly, the additional memory does not increase boot time. Moreover, because the MISR signature is small (e.g., only 1-2 KB of data compared to 36 KB of data for the seeds), the overall area for the two memories does not significantly increase. Thus, the larger size of the programmable ROM 530 does not affect the memory footprint. The full patterns are stored in the AIT ROM 506 and only the MISR signatures are stored in field programmable ROM 530. Due to the programmable nature of the programmable ROM 530, the MISR signature can be updated without redesigning the chip.

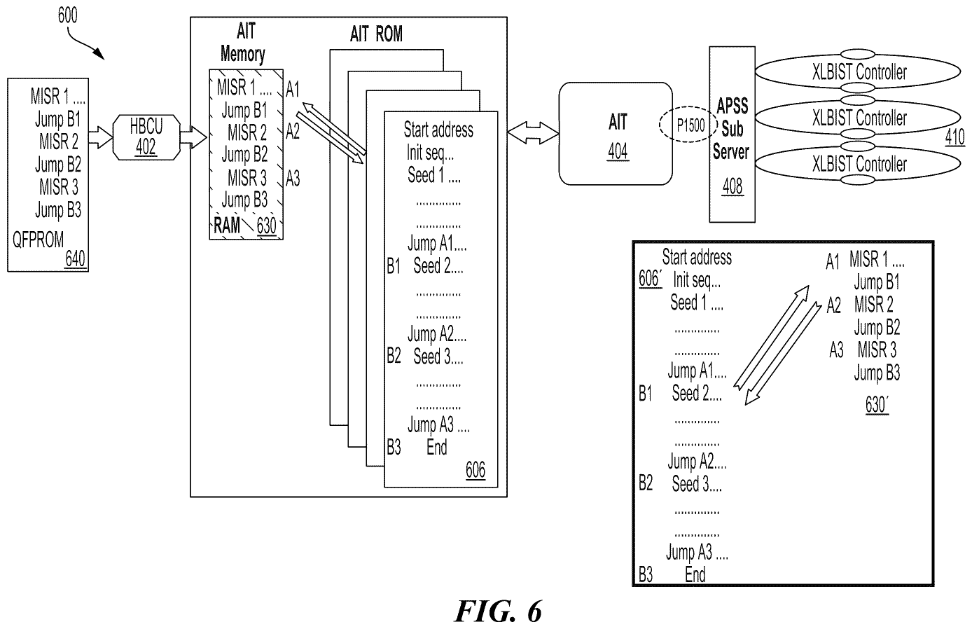

FIG. 6 is a block diagram illustrating a system 600 with random access memory (RAM) for storing logic built-in self-test (LBIST) multiple input signature register (MISR) patterns, in accordance with various aspects of the present disclosure. In the example of FIG. 6, the AIT ROM 406 of FIG. 4 is split into two separate memory spaces, including an AIT ROM 606 and an AIT RAM 630. The BIST MISR signature is separated from the BIST seeds and stored in the AIT RAM 630. As a result, the MISR signature can be programmed after post silicon validation.

A system level ROM 640 may store the MISR signature at a central location (e.g., off-chip). A sequencer of the HBCU 402 reads the MISR values from the off-chip ROM 640 and writes the MISR values to the AIT RAM 630. An advanced high performance bus (AHB) interface may be used for copying the MISR signature from the off-chip ROM 640 to the AIT RAM 630. Dedicated rows within the off-chip ROM 640 may be allocated for the MISR data. The MISR copy time takes less than 250 microseconds for 1 KB of data.

The AIT RAM 630 shares an address space with the AIT ROM 606. More specifically, as seen in the enlarged view of the AIT ROM 606′ and the enlarged view of the AIT RAM 630′, AIT JUMP instructions are inserted in the test pattern stored in the AIT ROM 606 to read MISR values from the AIT RAM 630. Jump instructions are also included in the AIT RAM 630 to jump back to the regular ROM addresses for further execution. As a result, the physical implementation of the split memory is transparent to the AIT controller 404. The AIT controller 404 does not see the actual memory physical implementation (e.g., AIT ROM 606 and AIT RAM 630). The AIT controller 404 sees the AIT ROM 606 and AIT RAM 630 as a single address space. Similar to the PROM 530, the AIT RAM 630 does not increase boot time.

As a result of segregating the MISR signature from the rest of the test pattern, any late timing exceptions (due to post silicon findings or fixes) leading to BIST MISR updates can be incorporated without redesigning the chip in increasing boot time. Aspects of the present disclosure segregate the MISR signature from the rest of the vector memory by adding a small amount (e.g., 1-2 KB) of programable ROM or RAM, instead of AIT ROM. The LBIST MISR signature may be stored in a dedicated field programmable ROM or RAM, instead of the regular ROM in a same AIT address space. AIT jump instructions to switch from the AIT ROM to programmable ROM or RAM for MISR reads and vice versa as part of the test pattern. For the RAM implementation, existing system PROM stores the MISR signature in dedicated spaces and rows. The HBCU copies data from the existing PROM to the RAM, for example with an AHB interface.

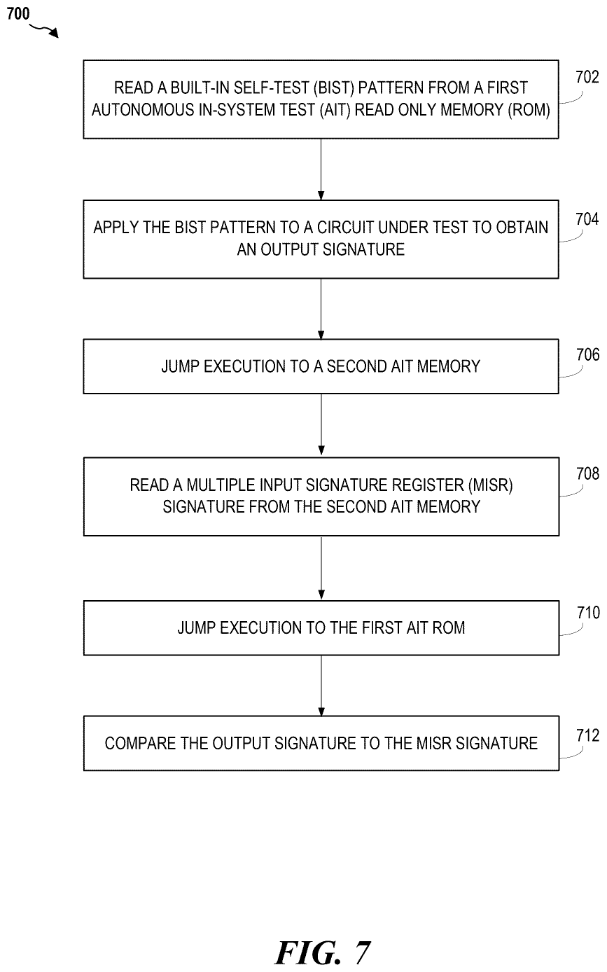

FIG. 7 is a flow chart illustrating an example process 700 performed, for example, by a built-in self-test (BIST) device, in accordance with various aspects of the present disclosure.

In some aspects, the process 700 may include reading a built-in self-test (BIST) pattern from a first autonomous in-system test (AIT) read only memory (ROM) (block 702). In some aspects, the process 700 may include applying the BIST pattern to a circuit under test to obtain an output signature (block 704).

In some aspects, the process 700 may include jumping execution to a second AIT memory (block 706). For example, the second AIT memory may comprises field programmable ROM (PROM) or random access memory (RAM).

In some aspects, the process 700 may include reading a multiple input signature register (MISR) signature from the second AIT memory (block 708).

In some aspects, the process 700 may include jumping execution to the first AIT ROM (block 710). In some aspects, the process 700 may include comparing the output signature to the MISR signature (block 712).

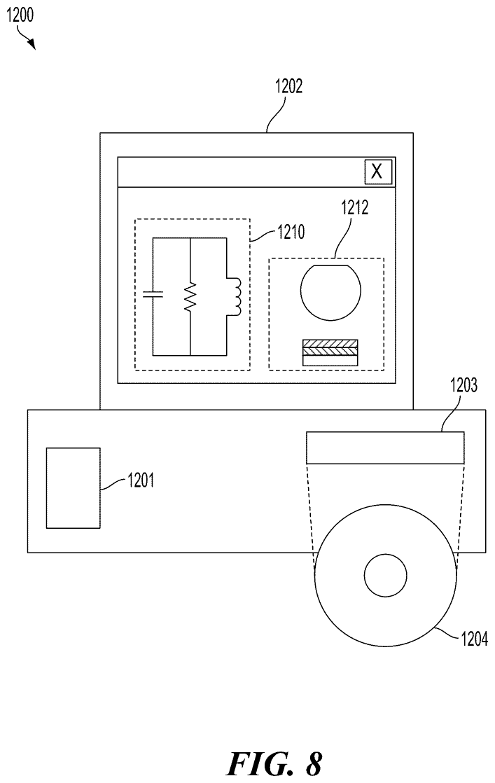

FIG. 8 is a block diagram illustrating a design workstation 800 used for circuit, layout, and logic design of a semiconductor component, such as the BIST device, disclosed above. The design workstation 800 includes a hard disk 801 containing operating system software, support files, and design software such as Cadence or OrCAD. The design workstation 800 also includes a display 802 to facilitate design of a circuit 810 or a semiconductor component 812, such as the safety mechanism. A storage medium 804 is provided for tangibly storing the design of the circuit 810 or the semiconductor component 812 (e.g., the BIST device). The design of the circuit 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the semiconductor component 812 by decreasing the number of processes for designing semiconductor wafers.

### Example Aspects

Aspect 1: An on-chip logic built-in self-test (LBIST) apparatus comprising: a first autonomous in-system test (AIT) read only memory (ROM) storing a built-in self-test (BIST) pattern and a first set of jump instructions for reading a multiple input signature register (MISR) signature from a second AIT memory; and the second AIT memory storing the MISR signature and a second set of jump instructions, the second set of jump instructions returning program execution to the first AIT ROM.

Aspect 2: The apparatus of Aspect 1, in which the second AIT memory comprises field programmable ROM (PROM).

Aspect 3: The apparatus of Aspect 1 or 2, in which the first AIT ROM and the programmable ROM share a same address space.

Aspect 4: The apparatus of Aspect 1, in which the second AIT memory comprises random access memory (RAM).

Aspect 5: The apparatus of Aspects 1 or 4, further comprising: a system level programmable ROM (PROM) storing the MISR signature; and a hardware BIST control unit coupled to the RAM and the system level PROM for copying the MISR signature to the RAM before BIST operations start.

Aspect 6: A method for performing a logic built-in self-test (LBIST) comprising: reading a built-in self-test (BIST) pattern from a first autonomous in-system test (AIT) read only memory (ROM); applying the BIST pattern to a circuit under test to obtain an output signature; jumping execution to a second AIT memory; reading a multiple input signature register (MISR) signature from the second AIT memory; jumping execution to the first AIT ROM; and comparing the output signature to the MISR signature.

Aspect 7: The method of Aspect 6, in which the second AIT memory comprises field programmable ROM (PROM).

Aspect 8: The method of Aspect 6 or 7, in which the first AIT ROM and the programmable ROM share a same address space.

Aspect 9: The method of Aspect 6, in which the second AIT memory comprises random access memory (RAM).

Aspect 10: The method of any of the Aspects 6 or 9, further comprising copying the MISR signature from a system level programmable ROM (PROM) to the RAM.

Aspect 11: The method of any of the Aspects 6-10, further comprising updating the MISR signature after silicon tape out.

Aspect 12: The method of any of the Aspects 6-11, further comprising triggering an autonomous in-system test (AIT) controller by a hardware BIST control unit during a boot operation.

Aspect 13: An apparatus for performing a logic built-in self-test (LBIST), comprising: at least one memory; and at least one processor coupled to the at least one memory, the at least one processor configured: to read a built-in self-test (BIST) pattern from a first autonomous in-system test (AIT) read only memory (ROM); to apply the BIST pattern to a circuit under test to obtain an output signature; to jump execution to a second AIT memory; to read a multiple input signature register (MISR) signature from the second AIT memory; to jump execution to the first AIT ROM; and to compare the output signature to the MISR signature.

Aspect 14: The apparatus of Aspect 13, in which the second AIT memory comprises field programmable ROM (PROM).

Aspect 15: The apparatus of Aspect 13-14, in which the first AIT ROM and the programmable ROM share a same address space.

Aspect 16: The apparatus of Aspect 13, in which the second AIT memory comprises random access memory (RAM).

Aspect 17: The apparatus of any of the Aspects 13 or 16, in which the at least one processor is further configured to copy the MISR signature from a system level programmable ROM (PROM) to the RAM.

Aspect 18: The apparatus of any of the Aspects 13-17, in which the at least one processor is further configured to update the MISR signature after silicon tape out.

Aspect 19: The apparatus of any of the Aspects 13-18, in which the at least one processor is further configured to trigger an autonomous in-system test (AIT) controller by a hardware BIST control unit during a boot operation.

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Generally, where there are operations illustrated in the figures, those operations may have corresponding counterpart means-plus-function components with similar numbering.

As used, the term “determining” encompasses a wide variety of actions. For example, “determining” may include calculating, computing, processing, deriving, investigating, looking up (e.g., looking up in a table, a database, or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general-purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read-only memory (ROM), flash memory, erasable programmable read-only memory (EPROM), electrically erasable programmable read-only memory (EEPROM), registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, random access memory (RAM), flash memory, read-only memory (ROM), programmable read-only memory (PROM), erasable programmable read-only memory (EPROM), electrically erasable programmable Read-only memory (EEPROM), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or general register files. Although the various components discussed may be described as having a specific location, such as a local component, they may also be configured in various ways, such as certain components being configured as part of a distributed computing system.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described. As another alternative, the processing system may be implemented with an application specific integrated circuit (ASIC) with the processor, the bus interface, the user interface, supporting circuitry, and at least a portion of the machine-readable media integrated into a single chip, or with one or more field programmable gate arrays (FPGAs), programmable logic devices (PLDs), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used, include compact disc (CD), laser disc, optical disc, digital versatile disc (DVD), floppy disk, and Blu-ray® disc where disks usually reproduce data magnetically, while discs reproduce data optically with lasers. Thus, in some aspects, computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented. For example, such a computer program product may comprise a computer-readable medium having instructions stored (and/or encoded) thereon, the instructions being executable by one or more processors to perform the operations described. For certain aspects, the computer program product may include packaging material.

Further, it should be appreciated that modules and/or other appropriate means for performing the methods and techniques described can be downloaded and/or otherwise obtained by a user terminal and/or base station as applicable. For example, such a device can be coupled to a server to facilitate the transfer of means for performing the methods described. Alternatively, various methods described can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

1. An on-chip logic built-in self-test (LBIST) apparatus comprising:
a first autonomous in-system test (AIT) read only memory (ROM) storing a built-in self-test (BIST) pattern and a first set of jump instructions for reading a multiple input signature register (MISR) signature from a second AIT memory; and
the second AIT memory storing the MISR signature and a second set of jump instructions, the second set of jump instructions returning program execution to the first AIT ROM.

2. The apparatus of claim 1, in which the second AIT memory comprises field programmable ROM (PROM).

3. The apparatus of claim 2, in which the first AIT ROM and the programmable ROM share a same address space.

4. The apparatus of claim 1, in which the second AIT memory comprises random access memory (RAM).

5. The apparatus of claim 4, further comprising:
a system level programmable ROM (PROM) storing the MISR signature; and
a hardware BIST control unit coupled to the RAM and the system level PROM for copying the MISR signature to the RAM before BIST operations start.

6. A method for performing a logic built-in self-test (LBIST) comprising:
reading a built-in self-test (BIST) pattern from a first autonomous in-system test (AIT) read only memory (ROM);
applying the BIST pattern to a circuit under test to obtain an output signature;
jumping execution to a second AIT memory;
reading a multiple input signature register (MISR) signature from the second AIT memory;
jumping execution to the first AIT ROM; and
comparing the output signature to the MISR signature.

7. The method of claim 6, in which the second AIT memory comprises field programmable ROM (PROM).

8. The method of claim 7, in which the first AIT ROM and the programmable ROM share a same address space.

9. The method of claim 6, in which the second AIT memory comprises random access memory (RAM).

10. The method of claim 9, further comprising copying the MISR signature from a system level programmable ROM (PROM) to the RAM.

11. The method of claim 6, further comprising updating the MISR signature after silicon tape out.

12. The method of claim 6, further comprising triggering an autonomous in-system test (AIT) controller by a hardware BIST control unit during a boot operation.

13. An apparatus for performing a logic built-in self-test (LBIST), comprising:
at least one memory; and
at least one processor coupled to the at least one memory, the at least one processor configured:
to read a built-in self-test (BIST) pattern from a first autonomous in-system test (AIT) read only memory (ROM);
to apply the BIST pattern to a circuit under test to obtain an output signature;
to jump execution to a second AIT memory;
to read a multiple input signature register (MISR) signature from the second AIT memory;
to jump execution to the first AIT ROM; and
to compare the output signature to the MISR signature.

14. The apparatus of claim 13, in which the second AIT memory comprises field programmable ROM (PROM).

15. The apparatus of claim 14, in which the first AIT ROM and the programmable ROM share a same address space.

16. The apparatus for of claim 13, in which the second AIT memory comprises random access memory (RAM).

17. The apparatus of claim 16, in which the at least one processor is further configured to copy the MISR signature from a system level programmable ROM (PROM) to the RAM.

18. The apparatus of claim 13, in which the at least one processor is further configured to update the MISR signature after silicon tape out.

19. The apparatus of claim 13, in which the at least one processor is further configured to trigger an autonomous in-system test (AIT) controller by a hardware BIST control unit during a boot operation.
